(19) United States
(12) Patent Application Publication
(10) Pub. No.: US 2007/0014081 A1
(43) Pub. Date: Jan. 18, 2007

(54) Bladder support heater device and method

(76) Inventor: Michael Caplin, Merrimack, NH (US)

Correspondence Address: SCOTT C. RAND, ESQ.;MCLANE, GRAF, RAULERSON & MIDDLETON, PA, 900 ELM STREET, P.O. BOX 326, MANCHESTER, NH, 03105-0326, US

(21) Appl. No.: 11/447,362

(22) Filed: Jun. 6, 2006

Related U.S. Application Data
(60) Provisional application No. 60/687,962, filed on Jun. 7, 2005.

(51) Int. Cl. H05K 5/00

(52) U.S. Cl. 361/679

(57) ABSTRACT

An apparatus for heating a circuit substrate includes a source of heated fluid, a flexible bladder in fluid communication with said source of heated fluid, a pump for delivering said heated fluid to said flexible bladder, and a pressure switch for sensing a pressure in said flexible bladder deactivating said pump when the pressure reaches a preselected value. In a further aspect, a method of heating and supporting a circuit board is provided

### CROSS REFERENCE TO RELATED APPLICATION

This application claims the benefit under 35 U.S.C. § 119(e) of U.S. provisional application Ser. No. 60/687,962 filed Jun. 7, 2005. The aforesaid provisional application is incorporated herein by reference in its entirety.

### BACKGROUND

The present disclosure generally relates to a bladder heater device. In particular, the present disclosure is directed to a bladder support heater device for both supporting and heating printed circuit boards (PCB) undergoing repairs.

Bottom side heating is typically an integral component to the circuit board repair process, particularly with regard to removal of leaded and balled components. The main function of bottom side heating is to reduce thermal bias, thereby allowing the circuit board to grow uniformly. Without bottom side heating, the local topside heat, which is applied to reflow a target component, would have negative effects on the circuit board as well as the repair process itself. The local heat would cause the PCB to expand in a small area thereby causing the PCB to buckle or “potato chip.” This may cause damage to the PCB by creating one or more non-planar areas on the surface of the PCB. The non-planar areas are damaging because they make it difficult to solder additional components to the PCB.

Known methods of bottom side heating include the following: local hot gas; area hot gas; infrared (IR); and combination IR/hot gas. Local hot gas heating generally has very limited use and is the least effective method as it may cause the same problems as local topside heating. Area hot gas heating may be effective at reducing the thermal bias, but it is difficult to control the thermal uniformity over the wide area of a heater array. IR heating can be uniform at the source. However, the absorption of the heat by the PCB is subject to emissivity of the PCB, i.e., darker areas tend to heat faster than lighter colored areas. IR is also the slowest form of heating.

In all bottom side heating cases, there is typically a need for bottom side circuit board support. As the PCB heats up, it tends to sag. This creates a non-planar site prohibiting proper contact with the replacement component or leads.

One known way to provide bottom side circuit board support is to strategically place tooling pins on the system work surface to support the PCB during the rework process. However, the proper placement of these pins, which is highly subject to operator error, is critical to a successful repair.

Another known way to provide bottom side circuit board support is to use fixed tooling to support the PCB. Although fixed tooling works well, it is costly to make and store.

Accordingly, the present disclosure contemplates a new and improved bladder support heater device which overcomes the above-referenced problems and others.

### SUMMARY

In one aspect of the disclosure, a bladder support heater device includes the following: a control unit including a closed loop heating control, a resistive heating element, a heating tank containing a fluid, a pump, a pressure switch, and logic; and a flexible bladder joined with the control unit via a hose. The closed loop heating control, which is programmed according to the logic, causes the fluid to be heated by the resistive heating element and pumped to the flexible bladder until the pressure switch causes the pump to turn off.

In another aspect of the disclosure, a method of heating and supporting a circuit board, includes the following steps: positioning a flexible bladder between a bottom surface of the circuit board and a machine surface; and inflating the flexible bladder with a heated fluid to a predetermined pressure and a predetermined temperature.

One advantage of the bladder support heater device described herein resides in its use of conduction, which provides an efficient form of heating and also provides the most thermal uniformity.

Another advantage of employing a heated fluid in a bladder is that it does not require that an electricity-powered heater be positioned adjacent the bladder or PCB surfaces.

Yet another advantage of the present development it that it provides a substrate with both thermal and mechanical stability through a flexible conductive heating apparatus during a rework cycle. The device will conform to the bottom side of a substrate to provide uniform conductive heating during a repair operation while also providing under side substrate support.

Still a further advantage of the present device is that it may be maintained in a substantially two-dimensional form when not inflated, i.e., not in use, versus prior art designs that are always three-dimensional, thereby saving space.

Still further benefits and advantages of the present disclosure will become apparent to those skilled in the art upon a reading and understanding of the preferred embodiments.

### BRIEF DESCRIPTION OF THE DRAWINGS

For the purpose of illustrating the invention, the drawings show a form of the invention that is presently preferred. However, it should be understood that the present invention is not limited to the precise arrangements and instrumentalities shown in the drawings, wherein:

FIG. 1 is a schematic diagram of a bladder support heater device according to one embodiment of the present invention

FIG. 2 is a cross-sectional view of a bladder support heater device in a typical installation between a machine surface and a PCB, according to one embodiment of the present invention; and

FIG. 3 is a flow chart outlining a method in accordance with an exemplary embodiment of the present invention.

### DETAILED DESCRIPTION OF THE PREFERRED EMBODIMENTS

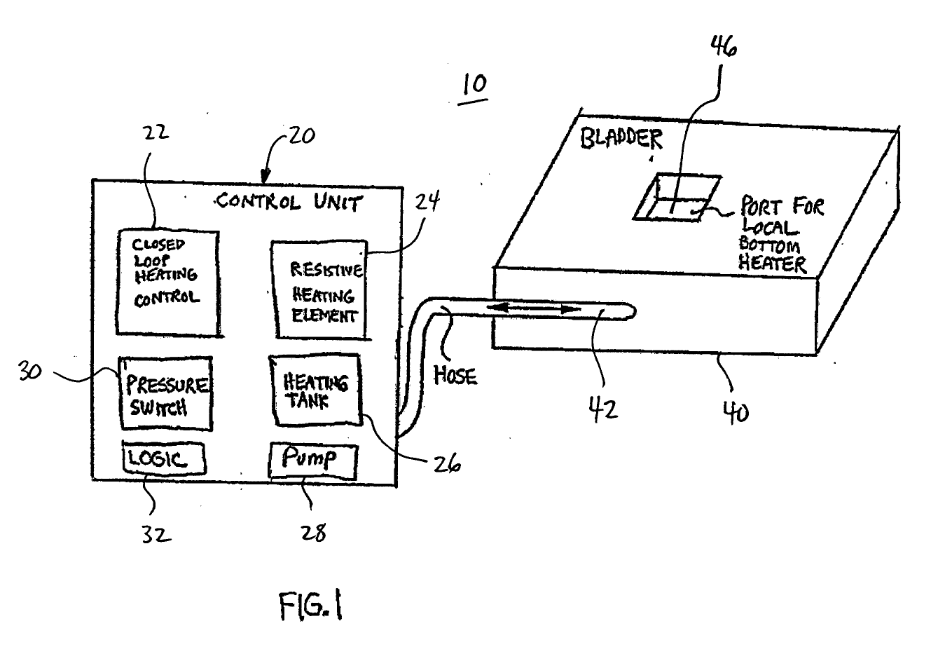

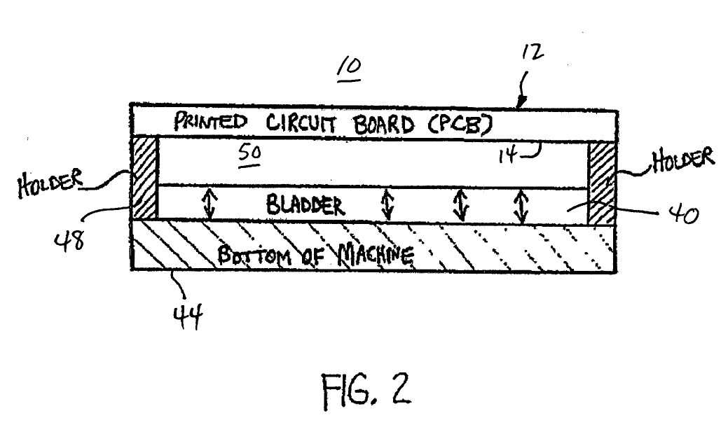

Referring now to the drawings in which like reference numerals indicate like parts, and in particular to FIGS. 1 and 2, there appears a thermally conductive bladder support heater device 10, which heats the bottom side 14 of a PCB 12 while providing tooling free support of the PCB 12. In one embodiment, the bladder support heater device 10 includes a control unit 20 and a flexible bladder 40, which are joined together via a hose 42. Fluid is heated in the control unit 20 and pumped through the hose 42 to the flexible bladder 40, thereby both inflating and heating the flexible bladder 40.

The control unit 20 includes a closed loop heating control 22, a resistive heating element 24, a heating tank or reservoir 26 containing a fluid, a pump 28, a pressure switch 30, and logic 32 which may be implemented in a microprocessor, microcontroller, controller, embedded controller, programmable logic device (PLD), field programmable gate array (FPGA) or field programmable object array (FPOA), or the like. Fluid is stored in the heating tank 26. Upon activation of the control unit 20 and according to predetermined or preselected parameters, which are programmed into the logic 32, the resistive heating element 24 is actuated to heat the fluid. The closed loop heating control 22, which monitors the temperature of the fluid via sensors, is used to control the resistive heating element 24 to ensure the fluid is heated to a predetermined value. The pump 28, which may be a gear pump or similar, is used to pump the heated fluid through the hose 42 to the flexible bladder. The pressure switch 30 deactivates the pump 28 when the pressure in the flexible bladder 40 reaches a predetermined or preselected value. Upon deactivation of the control unit 20, the fluid in the flexible bladder 40 gravity drains back to the heating tank 26 in the control unit 20, thereby deflating the flexible bladder 40.

Operation of the resistive heating element 24, the closed loop heating control 22, the pump 28, and the pressure switch 30 is interconnected with the programmed logic 32, which includes programming of cycle durations and frequencies for each component. Parameters such as the stiffness of the PCB 12, the anticipated load on the PCB 12, the distance between the machine surface 44 and the bottom 14 of the PCB 12, and the material characteristics of the flexible bladder 40 are all considered in developing the cycle durations and frequencies to be programmed into the logic device 32.

The flexible bladder 40 may be manufactured from materials that are flexible, heat resistant, puncture resistant, and non-reactive, e.g., rubber-based materials. One possible material may be a synthetic rubber sold under the brand name VITON® by DuPont Performance Elastomers LLC of Wilmington, Del.

In one embodiment, the bladder 40 includes a central port 46 adapted to receive an external localized bottom heater (not shown) such as a hot gas bottom heater. An external localized bottom heater allows a higher heat source to impinge gas at the direct underside of the specific site to be repaired.

Another aspect of the present disclosure is a method of heating and supporting a circuit board, which includes the steps of positioning a flexible bladder between a bottom surface of the circuit board and a machine surface and inflating the flexible bladder with a heated fluid to a predetermined pressure and a predetermined temperature. As best illustrated in FIG. 2, the unfilled, flexible bladder 40 is placed on the work surface 44 positioned under the substrate (e.g., PCB 12 in FIG. 2). At the start of the rework cycle, the control unit 20 pumps heated fluid up through the hose 42.

In the depicted embodiment, the apparatus 10 includes the work surface or base 44 and a raised peripheral wall 48 defining a cavity or recess 50. As the flexible bladder 40 fills, the gap between the bladder 40 and the substrate 12 is closed until the bladder 40 makes contact with the lower surface 14 of the substrate 12, thereby providing conductive heat to the substrate 12. The pressure switch 30 within the control unit 20 signals to stop pumping the heated fluid under preprogrammed control when a predetermined or preselected pressure is reached.

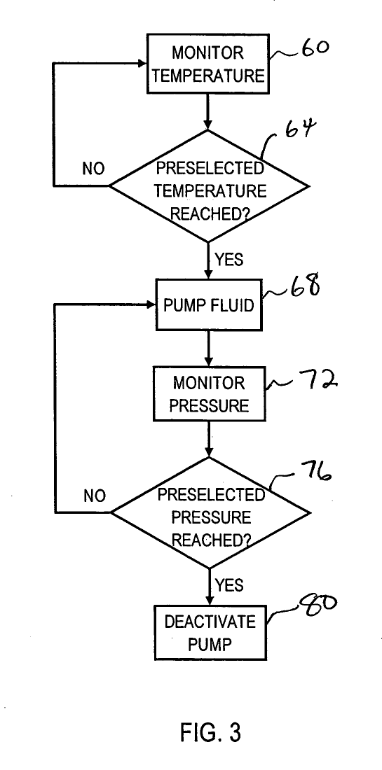

A flow chart in accordance with an exemplary embodiment appears in FIG. 3. The temperature of the heating fluid is monitored at step 60. At step 64, it is determined whether a predetermined or preselected temperature has been reached. If the preselected temperature has not been reached at step 64, the process returns to step 60. Once the desired temperature is achieved at step 64, the process proceeds to step 68 and the heated fluid is pumped to the bladder 40. At step 72, the pressure of the fluid is monitored. If a preselected or predetermined pressure has not been reached at step 76, the process returns to step 68. Once the desired pressure is reached, the pump 28 is deactivated at step 80.

The invention has been described with reference to the preferred embodiments. Obviously, modifications and alterations will occur to others upon reading and understanding the preceding detailed description. It is intended that the invention be construed as including all such modifications and alterations insofar as they come within the scope of the appended claims or the equivalents thereof.

Having thus described the preferred embodiments, the invention is now claimed to be:

1. A bladder support heater device, comprising:
a control unit including a closed loop heating control, a resistive heating element, a heating tank containing a fluid, a pump, a pressure switch, and logic; and
a flexible bladder joined with said control unit via a hose;
wherein said closed loop heating control, which is programmed according to said logic, causes said fluid to be heated by said resistive heating element and pumped to said flexible bladder until said pressure switch causes said pump to turn off.

2. A method of heating and supporting a circuit substrate, comprising:
positioning a flexible bladder between a bottom surface of the circuit substrate and a machine surface; and
inflating the flexible bladder with a heated fluid until a pressure in the flexible bladder reaches a preselected pressure.

3. An apparatus for heating a circuit substrate, comprising:
a source of heated fluid;
a flexible bladder in fluid communication with said source of heated fluid;
a pump for delivering said heated fluid to said flexible bladder; and
a pressure switch for sensing a pressure in said flexible bladder deactivating said pump when the pressure reaches a preselected value.

4. The apparatus of claim 3, wherein said source of heated fluid includes: a fluid reservoir, a heating element for heating fluid in said reservoir, and a closed loop heating control for controlling said heating element.

5. The apparatus of claim 4, further comprising:
a hose having an inlet in fluid communication with said pump and an outlet in fluid communication with said bladder.

6. The apparatus of claim 5, further comprising:
a work surface including a base and a vertically raised wall, the base and vertically raised wall defining a cavity for receiving said bladder; and
said vertically raised wall for supporting the circuit substrate.

7. The apparatus of claim 5, further comprising:
an aperture in said bladder for receiving a heat source.

8. The apparatus of claim 3, wherein the circuit substrate is a printed circuit board.
